(19) United States
(12) Patent Application Publication
(10) Pub. No.: US 2026/0292051 A1
(43) Pub. Date: Sep. 24, 2026

(54) IMPACT-RESISTANT PROTECTIVE ENCLOSURE

(71) Applicant: Adam HOLLIOAKE, Southport (AU)

(72) Inventor: Adam HOLLIOAKE, Southport (AU)

(21) Appl. No.: 19/490,035

(22) PCT Filed: Jun. 6, 2024
(86) PCT No.: PCT/AU2024/050592

§ 371 Date: Dec. 4, 2025

(30) Foreign Application Priority Data
Jun. 6, 2023 (AU) 2023901793

(51) Int. Cl. H04M 1/02; A45C 11/00

(52) U.S. Cl. CPC H04M 1/0203; A45C 11/002

(57) ABSTRACT

The present impact-resistant protective enclosure for mobile phones is designed to protect against high-energy impacts commonly encountered during sporting activities and other dynamic environments. The enclosure comprises a shell with an interior housing an electronic device securement mechanism. The shell features a front viewport aligned with the device's image sensor, allowing unobstructed use of the camera. The securement mechanism holds the mobile phone spaced apart from the shell, reducing shockwave transference. Additionally, the enclosure may include an energy impact attenuator between the front surface of the shell and the securement mechanism to further mitigate shockwave impact. The design ensures robust protection while maintaining the functionality and portability of the mobile phone, making it ideal for users engaged in active lifestyles.

### FIELD OF THE INVENTION

The present invention relates to protective enclosures for electronic devices, specifically mobile phones. More particularly, it pertains to impact-resistant enclosures designed to safeguard mobile phones from high-energy impacts encountered during activities such as sporting events, photography, and videography.

### BACKGROUND

In recent years, mobile phones have evolved to become essential tools for communication, media capture, and various other applications. With the integration of high-quality cameras, mobile phones are increasingly used for capturing photographs and videos in a wide range of environments, including sporting events. However, using mobile phones in such dynamic and often unpredictable settings exposes them to significant risks of physical damage.

Sporting events, in particular, present numerous hazards to mobile phones. Devices used in these environments can be subjected to high-impact forces, such as being struck by a ball or other sports equipment. Traditional protective cases, while effective against minor drops and scratches, often lack the necessary durability to protect against these more severe impacts. Such impacts can damage the phone's screen, camera, and internal components, leading to costly repairs or replacements.

Existing protective solutions for mobile phones have attempted to address these challenges by incorporating additional padding or rigid outer shells. However, these solutions often come with trade-offs. Bulky designs can hinder the portability and ease of use of the device, making it less convenient for users who rely on their mobile phones for spontaneous media capture. Additionally, protective cases that obstruct the camera can compromise the quality of photos and videos, which is a significant drawback for users who prioritize the photographic capabilities of their devices.

There is a growing demand for protective enclosures that provide robust protection against high-impact forces while maintaining the usability and functionality of mobile phones. Such enclosures need to balance durability with practicality, ensuring that the device remains easy to carry and use in a variety of settings. Moreover, they must offer clear and unobstructed access to the phone's camera to support high-quality media capture, even in challenging environments.

This demand highlights the need for innovative designs that can effectively shield mobile phones from severe impacts without adding excessive bulk or compromising the device's core functionalities. As mobile phones continue to play an integral role in capturing and sharing experiences, the development of advanced protective solutions becomes increasingly important. These solutions should cater to the needs of users who engage in active lifestyles, particularly those who participate in sports and outdoor activities, where the risk of impact damage is significantly higher.

### SUMMARY OF THE DISCLOSURE

The described electronic device protective enclosure is designed to safeguard mobile phone devices from ball impact during sporting photography and videography. It comprises a shell with an interior that houses an electronic device securement mechanism and features a front viewport. The securement mechanism holds the electronic device spaced from the shell, aligning the device's image sensor with the viewport to attenuate shockwave transference from the shell to the device.

The shell may be generally rectangular with long and short sidewalls. The securement mechanism spaces the device away from these sidewalls, and the shell's dimensions are generally larger than most mobile phone devices, ensuring adequate spacing to mitigate shockwave transference.

The securement mechanism preferably also holds the device away from the shell's front surface and may include an energy impact attenuator between the front surface and the engagement surface of the securement mechanism. This attenuator, which can feature ribbing or cross formations and be made of deformable materials like elastomeric material, reduces shockwave transference.

In one embodiment, the securement mechanism includes a clamp mechanism with opposing clamp members that move synchronously from an open to a closed position to clamp the device's edges. These clamp members may have longitudinally ribbed surfaces and be enclosed by a backing frame and a frontal plate. In another embodiment, the clamp mechanism is simplified to a single movable jaw portion that slides along a track. This jaw portion may be moved by a tension spring, or a threaded screw engaged by an external tightening knob, providing greater tension.

The rear of the shell may be enclosed with a cover that has a window for viewing the device's display. This window may be open for pressing on-screen buttons or enclosed with a plastic film for capacitive touch sensing. The cover may be removable, featuring interlocking male and female hinge portions and a latch with a notch that engages a transverse pin. A transparent portion may form the viewport.

The enclosure may include support attachments on at least one sidewall for connecting a support such as a tripod. These attachments may have a threaded blind hole and be located in thicker sections of the sidewalls for structural resilience. Multiple sidewalls may have support attachments, allowing the device to be oriented in various positions. The enclosure may also have a vent grille to allow hot air to escape.

Other aspects of the invention are also disclosed.

### BRIEF DESCRIPTION OF THE DRAWINGS

Notwithstanding any other forms which may fall within the scope of the present invention, preferred embodiments of the disclosure will now be described, by way of example only, with reference to the accompanying drawings in which:

FIG. 1 shows an electronic device protective enclosure in accordance with a first embodiment;

FIG. 2 shows a perspective disassembled view of the protective enclosure;

FIG. 3 shows a clamp member synchronising mechanism in accordance with an embodiment;

FIG. 4 shows a rear of the protective enclosure with exemplary dimensions;

FIG. 5 shows a side of the protective enclosure with exemplary dimensions;

FIG. 6 shows a perspective disassembled view of the protective enclosure in accordance with a second embodiment;

FIG. 7 shows a rear view of the enclosure according to the second embodiment; and FIG. 8 shows a bottom view of the enclosure according to the second embodiment.

### DESCRIPTION OF EMBODIMENTS

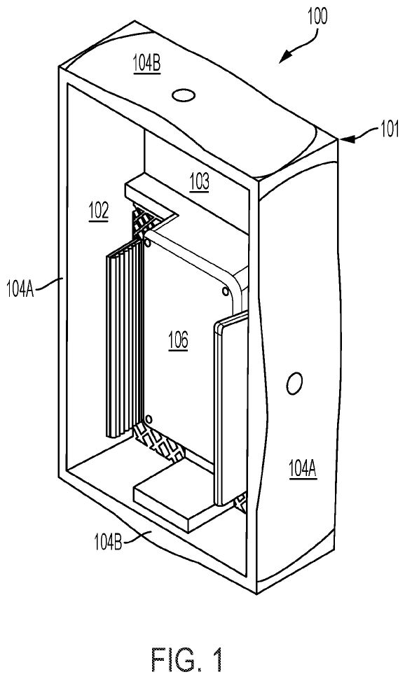

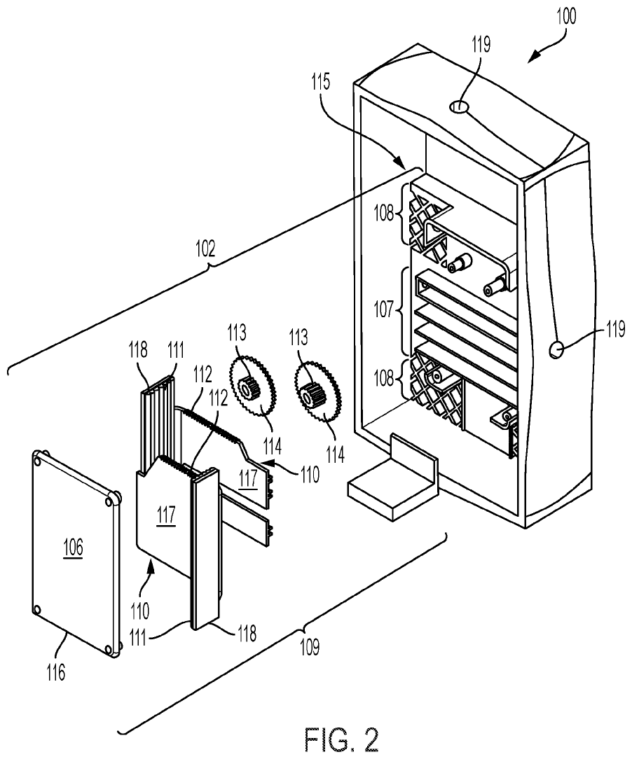

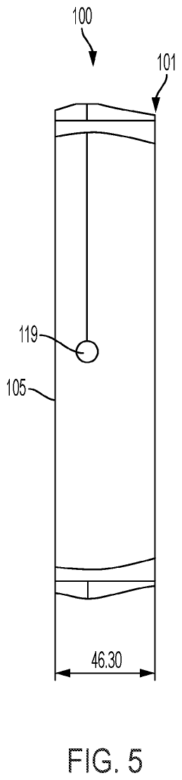

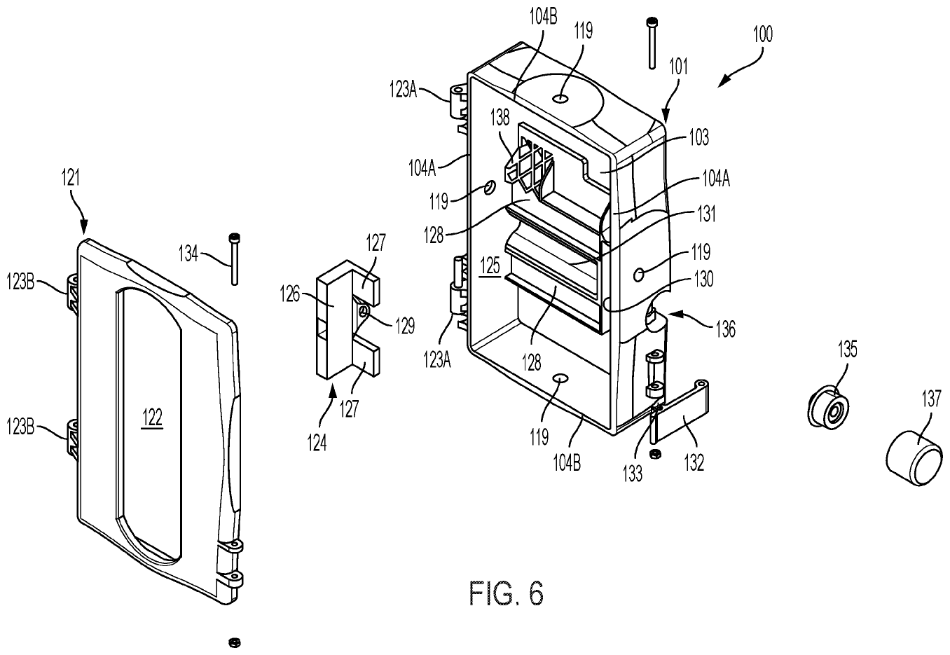

FIGS. 1-5 show a first embodiment of a protective enclosure 100 designed for protecting electronic devices (such as mobile phones) from ball impact when used for sporting photography and videography. FIGS. 6-8 show a second embodiment of the enclosure 100.

The enclosure 100 defines a shell 101 with an interior that houses an electronic device securement mechanism 102. The shell 101 also features a front viewport 103. The electronic device securement mechanism 102 is configured to hold an electronic device spaced from the shell 101, with the device's image sensor aligned with the viewport 103. The spacing of the electronic device from the shell 101 attenuates shockwave transference from the shell to the electronic device.

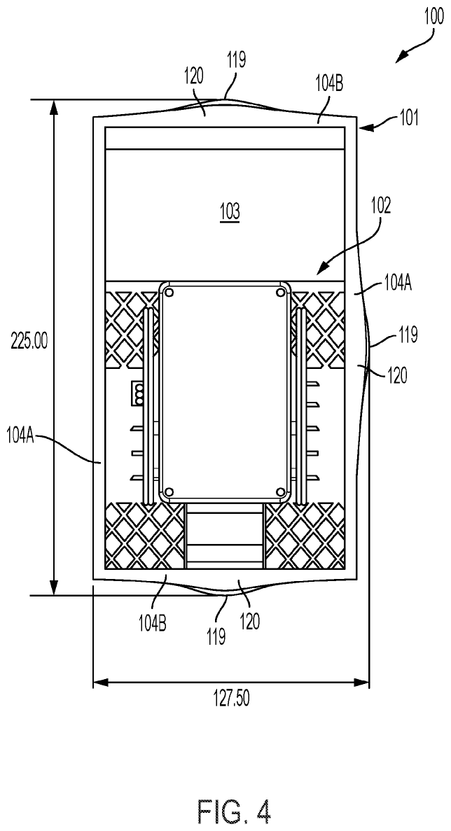

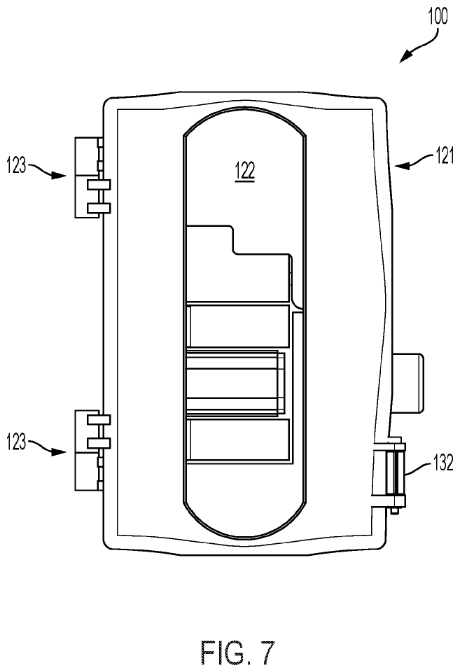

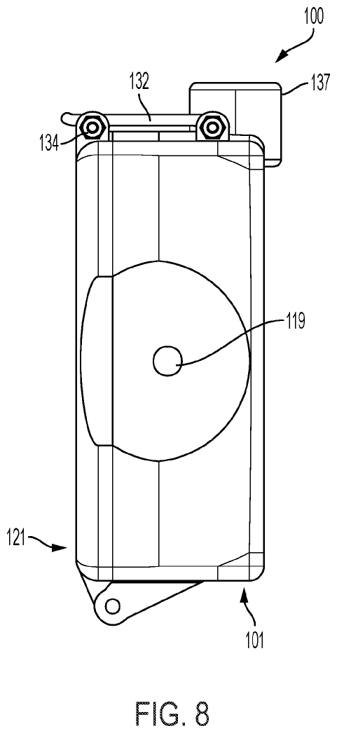

The shell 101 has sidewalls 104 and may be generally rectangular, with long sidewalls 104A and short sidewalls 104B. The electronic device securement mechanism 102 is preferably configured to space the electronic device away from the sidewalls 104. According to the exemplary dimensions shown in FIG. 4, the shell 101 is relatively wide, with short sidewalls 104B exceeding 120 mm, preferably approximately 127 mm as shown. Furthermore, the shell 101 is relatively tall, with long sidewalls 104A exceeding 200 mm, preferably approximately 225 mm. According to FIG. 7, the second embodiment of the enclosure may have a width (including the hinges 123) of approximately 148 mm and a height of approximately 197 mm. According to FIG. 8, the enclosure 100 may have a depth of approximately 51.3 mm. These dimensions are generally larger than most commercially available mobile phone devices, thereby adequately spacing the electronic device away from the sidewalls 104 to attenuate shockwave transference from the sidewalls to the electronic device.

Furthermore, the securement mechanism 102 is preferably configured to hold the electronic device spaced from a front surface 105 of the shell 101. The enclosure 100 may comprise an energy impact attenuator between the front surface 105 and an engagement surface 106 of the securement mechanism 102. The energy impact attenuator reduces shockwave transference between the front surface 105 and the engagement surface 106, which directly engages the front surface of the electronic device. The energy impact attenuator may feature energy absorption formations, such as ribbing 107 and/or cross formations 108. It may also be made of material that deforms under impact, such as elastomeric material. For example, the cross formations 108 may be formed as a moulded silicon mat.

In the first embodiment, the securement mechanism 102 preferably comprises a clamp mechanism 109 configured to clamp opposing edges of the electronic device in use. Preferably, the clamp mechanism 109 is configured to clamp the long edges of the electronic device. The clamp mechanism 109 may consist of opposing clamp members 110 with inwardly oriented opposing clamp surfaces 111, which move from an open position to a closed position to clamp the edges of the electronic device. The opposing clamp surfaces 111 may be longitudinally ribbed. The clamp members 110 preferably move synchronously between the open and closed positions. Each clamp member 110 may feature a rack 112 that turns a pinion 113 of a respective synchronising mesh gear 114. The clamp members 110 may have slidably overlapping backing plates 117 and orthogonal side plates 118 defining the inwardly oriented opposing clamp surfaces 111. The securement mechanism 102 may further comprise a backing frame 115 and a frontal plate 116 enclosing the opposing clamp members 110.

In the second embodiment, as shown in FIG. 6, the clamp mechanism 109 is simplified and consists of a single movable jaw portion 124 that slides along a track. The jaw portion 124 may be right-angled, comprising a side wall 126 and orthogonal feet 127. The orthogonal feet slide within respective channels 128 of the track 125. The jaw portion 124 may have a tab 129 with an aperture that engages a tension spring (not shown) oppositely coupled to an aperture 130 at the opposite end of the track 125, pulling the jaw portion 124 across the track 125 so that the side wall 126 presses against the side of the mobile phone device. The track 125 may have a recess 131 that accommodates the tension spring.

In alternative embodiments, the tab 129 is urged sideways by a nut 135 engaging a threaded screw retained along the recess 131, extending through a side opening 136 in the enclosure to engage a tightening knob 137. The externally located tightening knob 137 can turn the screw to tighten the movable jaw portion 124 against the side of the mobile phone device. As shown in FIG. 8, the knob 137 may be located so that a side of the knob 137 extends accessibly beyond the front surface of the enclosure 100. The threaded screw mechanism may achieve greater tension compared to the tension spring.

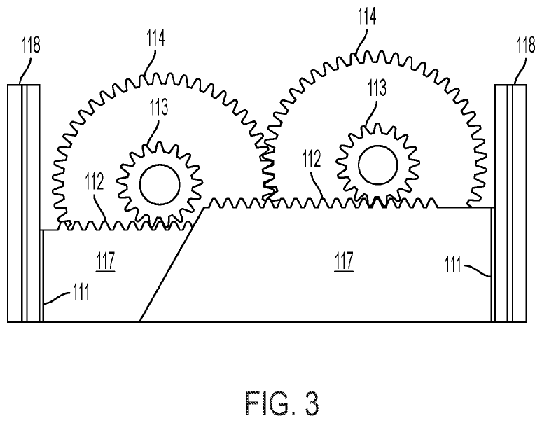

In the second embodiment, the clamp mechanism 109 is simplified, comprising only a single movable jaw portion 124 compared to the synchronised gear arrangement shown in FIG. 3. This simplified embodiment is generally applicable to most commercial types of mobile phone devices, with their image sensor devices arranged to one side, aligning with the viewport 103.

The rear of the shell 101 may be enclosed with a cover 121, which may have a window 122 to allow viewing of the mobile phone device's digital display. Preferably, the window 122 is open to facilitate pressing of on-screen recording buttons. In this regard, the window 122 is preferably open at a bottom end of the enclosure to thereby collocate with typical locations of on-screen recording buttons. However, in embodiment shown in FIG. 7, the window 127 may extend substantially along the entire length of the cover 121. In embodiments, the window 122 may be enclosed with a plastic film that allows for capacitive touch sensing operation of on-screen recording buttons. The cover 121 may be removable, with the enclosure 100 comprising male hinge portions 123A and female hinge portions 123B that slidably interlock to form hinges 123. A latch 132 opposite the hinges 123 may secure the cover 121 closed. The latch 132 may feature a notch 133 that engages a transverse pin 134. A transparent portion may form the viewport 103.

At least one sidewall 104 may define a support attachment 119 for attaching a support, such as a tripod. The support attachment 119 may comprise a threaded blind hole to engage a conventional tripod screw. The sidewalls 104 may have a thicker section at the support attachment 119 for structural resilience. Preferably, more than one sidewall 104 may define a respective support attachment 119, allowing the electronic device to be oriented in landscape or portrait orientation. Further, both short sidewalls 104B may have respective support attachments 119, enabling the electronic device to be oriented in both upright and inverted portrait orientations. According to FIG. 6, the enclosure 100 may also comprise a vent grille 138 to allow hot air to escape from the enclosure.

The foregoing description, for purposes of explanation, used specific nomenclature to provide a thorough understanding of the invention. However, it will be apparent to one skilled in the art that specific details are not required in order to practise the invention. Thus, the foregoing descriptions of specific embodiments of the invention are presented for purposes of illustration and description. They are not intended to be exhaustive or to limit the invention to the precise forms disclosed as obviously many modifications and variations are possible in view of the above teachings. The embodiments were chosen and described in order to best explain the principles of the invention and its practical applications, thereby enabling others skilled in the art to best utilize the invention and various embodiments with various modifications as are suited to the particular use contemplated. It is intended that the following claims and their equivalents define the scope of the invention.

1. An electronic device protective enclosure comprising a shell defining an interior and a front viewport, and having an electronic device securement mechanism therein, wherein the electronic device securement mechanism is configured in use to hold an electronic device spaced apart from the shell with an image sensor of the electronic device aligned with the viewport.

2. The enclosure as claimed in claim 1, wherein the shell defines sidewalls and the electronic device securement mechanism is configured to space the electronic device away from the sidewalls.

3. The enclosure as claimed in claim 2, wherein the sidewalls include short sidewalls wider than 120 mm.

4. The enclosure as claimed in claim 2, wherein the sidewalls include long sidewalls longer than 190 mm.

5. The enclosure as claimed in claim 2, wherein the securement mechanism is configured to hold the electronic device spaced apart from a front surface of the shell.

6. The enclosure as claimed in claim 5, further comprising an energy impact attenuator between the front surface and an engagement surface of the securement mechanism.

7. The enclosure as claimed in claim 6, wherein the attenuator comprises energy absorption formations.

8. The enclosure as claimed in claim 7, wherein the energy absorption formations comprise ribbing.

9. The enclosure as claimed in claim 7, wherein the energy absorption formations comprise cross formations.

10. The enclosure as claimed in claim 6, wherein the energy impact attenuator comprises a material which compresses or deforms under impact.

11. The enclosure as claimed in claim 10, wherein the energy impact attenuator comprises elastomeric material.

12. The enclosure as claimed in claim 1, wherein the securement mechanism comprises a clamp mechanism configured to secure the electronic device.

13. The enclosure as claimed in claim 12, wherein the clamp mechanism is configured to opposingly clamp edges of the electronic device in use.

14. The enclosure as claimed in claim 12, wherein the clamp mechanism is configured to clamp long edges of the electronic device in use.

15. The enclosure as claimed in claim 12, wherein the clamp mechanism comprises opposing clamp members defining inwardly oriented opposing clamp surfaces, and wherein the clamp members move oppositely from an open position to a closed position.

16. The enclosure as claimed in claim 15, wherein the clamp members move synchronously between the open and closed positions.

17. The enclosure as claimed in claim 16, wherein each clamp member defines a rack which turns a pinion of a respective synchronising mesh gear.

18. The enclosure as claimed in claim 15, wherein the securement mechanism comprises a backing frame and a frontal plate enclosing the opposing clamp members.

19. The enclosure as claimed in claim 12, wherein the clamp members define respective slidably overlapping backing plates and orthogonal side plates defining the inwardly oriented opposing clamp surfaces.

20. The enclosure as claimed in claim 12, wherein the clamp mechanism comprises a single movable jaw portion which slides along a track.

21. The enclosure as claimed in claim 20, wherein the movable jaw portion is right-angled and defines a side wall and orthogonal feet, wherein the orthogonal feet slide within respective channels defined by the track.

22. The enclosure as claimed in claim 20, wherein a tension spring engaged by the movable jaw portion slides the movable jaw portion along the track.

23. The enclosure as claimed in claim 22, wherein the track defines a recess which fits the tension spring therein.

24. The enclosure as claimed in claim 20, wherein the movable jaw portion is urged sideways by a threaded screw.

25. The enclosure as claimed in claim 24, wherein the threaded screw extends through the shell to engage an external tightening knob.

26. The enclosure as claimed in claim 25, wherein a side of the tightening knob accessibly extends beyond a front surface of the enclosure.

27. The enclosure as claimed in claim 1, wherein a rear of the shell is enclosed with a cover.

28. The enclosure as claimed in claim 27, wherein the cover has a window for operation of a recording button of the electronic device.

29. The enclosure as claimed in claim 28, wherein the window is open at a bottom portion of the electronic device.

30. The enclosure as claimed in claim 1, wherein at least one sidewall defines a support attachment.

31. The enclosure as claimed in claim 30, wherein the support attachment comprises a threaded blind hole.

32. The enclosure as claimed in claim 30, wherein the sidewalls define a thicker section coincident with the support attachment.

33. The enclosure as claimed in claim 30, wherein at least one long and one short sidewall define a respective support attachment.

34. The enclosure as claimed in claim 30, wherein both opposite short sidewalls define a respective support attachment.

35. The enclosure as claimed in claim 1, wherein the shell has a vent grille.
